(19) United States
(12) Patent Application Publication
(10) Pub. No.: US 2024/0251553 A1
(43) Pub. Date: Jul. 25, 2024

(54) SEMICONDUCTOR MEMORY DEVICE AND METHOD OF FABRICATING THE SAME

(71) Applicant: Samsung Electronics Co., Ltd., Suwon-si (KR)

(72) Inventors: Young Bong SHIN, Suwon-si (KR); Ji Hoon LEE, Suwon-si (KR); Mi Hye KANG, Suwon-si (KR); Jun Hee NA, Suwon-si (KR); Phil Ouk NAM, Suwon-si (KR); Tae Gi YEH, Suwon-si (KR)

(73) Assignee: Samsung Electronics Co., Ltd., Suwon-si (KR)

(21) Appl. No.: 18/493,122

(22) Filed: Oct. 24, 2023

(30) Foreign Application Priority Data
Jan. 20, 2023 (KR) 10-2023-0008758

(51) Int. Cl. H10B 43/27; H10B 41/10; H10B 41/27; H10B 41/35; H10B 41/40; H10B 43/10; H10B 43/35; H10B 43/40

(52) U.S. Cl. CPC H10B 43/27; H10B 41/10; H10B 41/27; H10B 41/35; H10B 41/40; H10B 43/10; H10B 43/35; H10B 43/40

(57) ABSTRACT

A semiconductor memory device includes a stack structure on a substrate, extending in a first direction, and including gate electrode layers and insulating layers stacked alternately with each other, a vertical structure including a vertical channel film extending in a second direction crossing the first direction and a channel insulating film disposed on the vertical channel film and having first areas adjacent to the insulating layers and second areas adjacent to the gate electrode layers, and a high-k film on the channel insulating film. The high-k film includes a first high-k metal oxide film between the first areas and the insulating layers and in contact with the first areas and a second high-k metal oxide film between the second areas and the gate electrode layers and in contact with the second areas, and the first and second high-k metal oxide films include different metal materials.

### CROSS-REFERENCE TO RELATED APPLICATION

This application claims priority from Korean Patent Application No. 10-2023-0008758 filed on Jan. 20, 2023 in the Korean Intellectual Property Office, and all the benefits accruing therefrom under 35 U.S.C. 119, the contents of which in its entirety are herein incorporated by reference.

### BACKGROUND

Various example embodiments relate to a semiconductor memory device and/or a method of fabricating the same, and more particularly, to a three-dimensional semiconductor memory device including a vertical channel film and having improved performance and/or reliability, and/or a method of fabricating the same.

As semiconductor memory devices capable of storing high-capacity data are required or desired, research into methods for increasing data storage capacity of the semiconductor memory devices has been conducted. As one of the methods for increasing the data storage capacity of the semiconductor memory devices, a semiconductor memory device including three-dimensionally arranged memory cells instead of two-dimensionally arranged memory cells has been proposed.

### SUMMARY

Various example embodiments provide a semiconductor memory device including a vertical structure having improved element performance and/or reliability.

Alternatively or additionally, various example embodiments also provide a method of fabricating a semiconductor memory device including a vertical structure having improved element performance and/or reliability.

However, aspects are not restricted to those set forth herein. The above and other aspects of inventive concepts will become more apparent to one of ordinary skill in the art to which the present disclosure pertains by referencing the detailed description of the present disclosure given below.

According to some example embodiments, a semiconductor memory device includes a stack structure on a substrate, extending in a first direction, and including gate electrode layers and insulating layers stacked alternately with each other, a vertical structure including a vertical channel film extending in a second direction crossing the first direction and a channel insulating disposed on the vertical channel film and having first areas adjacent to the insulating layers and second areas adjacent to the gate electrode layers, and a high-k film on the channel insulating film. The high-k film includes a first high-k metal oxide film between the first areas and the insulating layers and in contact with the first areas and a second high-k metal oxide film between the second areas and the gate electrode layers and in contact with the second areas, and the first and second high-k metal oxide films include different metal materials.

Alternatively or additionally according to some example embodiments, a semiconductor memory device includes a stack structure on a substrate and including gate electrode layers and insulating layers stacked alternately with each other, a vertical structure including a vertical channel film and a channel insulating film and extending in a direction in which the vertical channel penetrates through the stack structure, the channel insulating film including a tunnel insulating film, a charge storing film, and a blocking insulating film sequentially arranged on the vertical channel film and having first areas adjacent to the insulating layers and second areas adjacent to the gate electrode layers, a passivation film between the channel insulating film and the insulating layers, a first high-k metal oxide film on the first areas and in contact with the blocking insulating film, and a second high-k metal oxide film on the second areas and in contact with the blocking insulating film, The first and second high-k metal oxide films include different metal materials.

Alternatively or additionally according to some example embodiments, a method of fabricating a semiconductor memory device includes forming a pre-stack structure on a substrate, the pre-stack structure including sacrificial layers and insulating layers that are alternately stacked, forming channel holes penetrating through the pre-stack structure, sequentially forming a passivation film and a first high-k metal oxide film in the channel holes, sequentially forming a blocking insulating film, a charge storing film, a tunnel insulating film, and a pre-channel film on the first high-k metal oxide film, removing the sacrificial layers to expose portions of the passivation film, removing the exposed portions of the passivation film to expose portions of the first high-k metal oxide film, removing the exposed portions of the first high-k metal oxide film to expose portions of the blocking insulating film, forming a second high-k metal oxide film including a metal material different from that of the first high-k metal oxide film, the second high-k metal oxide film formed so as to be in contact with the exposed blocking insulating film, and forming gate electrode layers on the second high-k metal oxide film.

Other detailed features of example embodiments are described in a detailed description and are illustrated in the drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an illustrative block diagram for describing a semiconductor memory device according to some exemplary embodiments;

FIG. 2 is an illustrative circuit diagram for describing the semiconductor memory device according to some example embodiments;

FIG. 3 is a schematic layout diagram for describing the semiconductor memory device according to some example embodiments;

FIG. 4 is a cross-sectional view taken along line A-A of FIG. 3;

FIG. 5 is an enlarged view of area R1 of FIG. 4;

FIG. 6 is an enlarged view of area R2 of FIG. 4;

FIG. 7 is a view for describing a semiconductor memory device according to some example embodiments;

FIG. 8 is a view for describing a semiconductor memory device according to some example embodiments;

FIG. 9 is a view for describing a semiconductor memory device according to some example embodiments;

FIGS. 10 to 23 are views for describing intermediate steps of a method of fabricating a semiconductor memory device according to some example embodiments;

FIG. 24 is an illustrative block diagram for describing an electronic system according to some example embodiments;

FIG. 25 is an illustrative perspective view for describing an electronic system according to some example embodiments; and

FIG. 26 is a schematic cross-sectional view of a semiconductor package according to some example embodiments.

### DETAILED DESCRIPTION OF VARIOUS EXAMPLE EMBODIMENTS

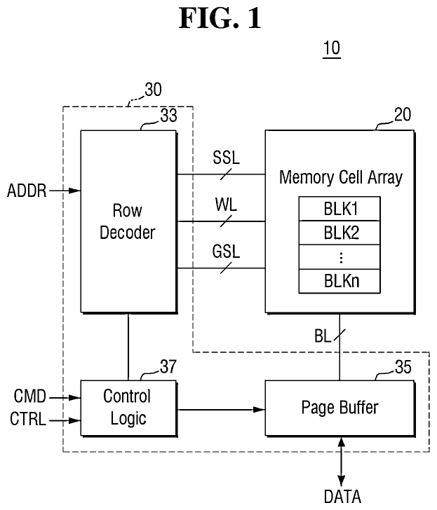

FIG. 1 is an illustrative block diagram for describing a semiconductor memory device according to some example embodiments.

Referring to FIG. 1, a semiconductor memory device 10 according to some example embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. In some example embodiments, the memory cell blocks BLK1 to BLKn may be connected to a row decoder 33 through the word line WL, the string selection line SSL, and the ground selection line GSL. In some example embodiments, the memory cell blocks BLK1 to BLKn may be connected to a page buffer 35 through the bit line BL.

The peripheral circuit 30 may receive an address ADDR, a command CMD, and a control signal CTRL, each from the outside of the semiconductor memory device 10, e.g., from a host device (not shown), and may transmit and receive data DATA to and from a device positioned outside the semiconductor memory device 10, e.g., from the host device. The peripheral circuit 30 may include a control logic 37, the row decoder 33, and the page buffer 35. Although not illustrated in FIG. 1, the peripheral circuit 30 may further include various sub-circuits such as one or more of an input/output circuit, a voltage generating circuit generating various voltages required for an operation of the semiconductor memory device 10, and an error correction circuit for correcting an error of data DATA read from the memory cell array 20.

The control logic 37 may be connected to the row decoder 33, the input/output circuit, and the voltage generating circuit. The control logic 37 may control up to an overall operation of the semiconductor memory device 10. The control logic 37 may generate various internal control signals used in the semiconductor memory device 10 in response to the control signal CTRL. For example, the control logic 37 may adjust voltage levels provided to the word line WL and the bit line BL when a memory operation such as a program operation or an erase operation is performed.

The row decoder 33 may select at least one of the plurality of memory cell blocks BLK1 to BLKn in response to the address ADDR, and may select at least one word line WL, at least one string selection line SSL, and at least one ground selection line GSL of the selected memory cell blocks BLK1 to BLKn. In some example embodiments, the row decoder 33 may transmit a voltage for performing a memory operation to the word lines WL of the selected memory cell blocks BLK1 to BLKn.

The page buffer 35 may be connected to the memory cell array 20 through the bit line BL. The page buffer 35 may operate as a writer driver and/or as a sense amplifier. For example, when the program operation is performed, the page buffer 35 may operate as the write driver to apply a voltage according to data DATA that is to be stored in the memory cell array 20 to the bit line BL. Meanwhile, when a read operation is performed, the page buffer 35 may operate as the sense amplifier to sense data DATA stored in the memory cell array 20.

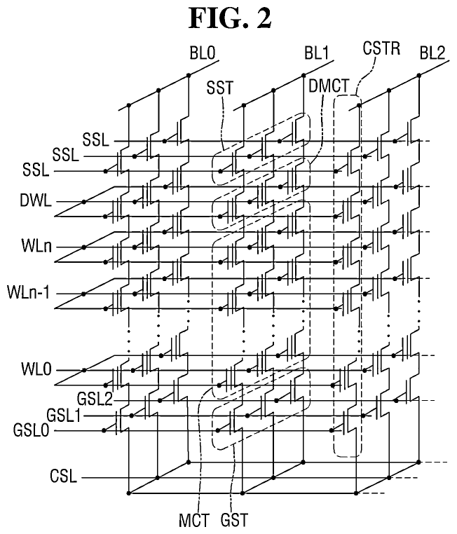

FIG. 2 is an illustrative circuit diagram for describing the semiconductor memory device according to some example embodiments.

Referring to FIG. 2, the memory cell array of the semiconductor memory device according to some example embodiments may include a common source line CSL, a plurality of bit lines BL0 to BL2, and a plurality of cell strings CSTR disposed between the common source line CSL and the bit lines BL0 to BL2.

The plurality of cell strings CSTR may be connected to each of the bit lines BL0 to BL2 in parallel. The plurality of cell strings CSTR may be commonly connected to the common source line CSL. For example, the plurality of cell strings CSTR may be disposed between the plurality of bit lines BL0 to BL2 and one common source line CSL. A plurality of common source lines CSL may be two-dimensionally arranged. Here, the electrically same voltage may be applied to the common source lines CSL, or each of the common source lines CSL may be electrically controlled.

For example, each of the cell strings CSTR may include a string selection transistor SST, memory cells MCT connected to each other in series, and a ground selection transistor GST. In some example embodiments, each of the memory cells MCT includes a data storage element.

As an example, each of the cell strings CSTR may include a string selection transistor SST connected to the bit lines BL0 to BL2 in series. The ground selection transistor GST may be connected to the common source line CSL. The memory cells MCT may be connected in series between the string selection transistor SST and the ground selection transistor GST.

Furthermore, each of the cell strings CSTR may further include a dummy cell DMCT connected between the string selection transistor SST and the memory cell MCT.

Although not illustrated in the drawings, the dummy cell DMCT may also be connected between the ground selection transistor GST and the memory cell MCT. Alternatively or additionally, the ground selection transistor GST in each of the cell strings CSTR may include a plurality of metal oxide semiconductor (MOS) transistors connected to each other in series. Alternatively or additionally, each of the cell strings CSTR may include a plurality of string selection transistors connected to each other in series. Alternatively or additionally, each of the cell strings CSTR may further include erase control transistors disposed between the bit lines BL0 to BL2 and the string selection transistors SST. The erase control transistors may be connected to the string selection transistor SST in series.

According to some example embodiments, the string selection transistor SST may be controlled by the string selection line SSL. The memory cells MCT may be controlled by a plurality of word lines WL0 to WLn, and the dummy cells DMCT may be controlled by a dummy word line DWL. In some example embodiments, the ground selection transistor GST may be controlled by the ground selection line GSL. The common source line CSL may be commonly connected to sources of the ground selection transistors GST.

One cell string CSTR may include a plurality of memory cells MCT having different distances from the common source lines CSL. In some example embodiments, a plurality of word lines WL0 to WLn and DWL may be disposed between the common source lines CSL and the bit lines BL0 to BL2.

Gate electrodes of the memory cells MCT which are disposed at substantially the same distance from the common source lines CSL may be commonly connected to one of the word lines WL0 to WLn and DWL to be in an equipotential (same voltage) state. Alternatively, although the gate electrodes of the memory cells MCT are disposed at substantially the same level from the common source lines CSL, the gate electrodes disposed in different rows and/or columns may be independently controlled.

Ground selection lines GSL0 to GSL2 and the string selection lines SSL may extend in the same direction as the word lines WL0 to WLn and DWL, for example. The ground selection lines GSL0 to GSL2 and the string selection line SSL disposed at substantially the same level from the common source lines CSL may be electrically separated from each other.

Although not illustrated in the drawings, when the cell string CSTR includes erase control transistors, the erase control transistors may be controlled by a common erase control line. The erase control transistors generate gate induced drain leakage (GIDL) at the time of an erase operation of the memory cell array. That is, the erase control transistors may be GIDL transistors.

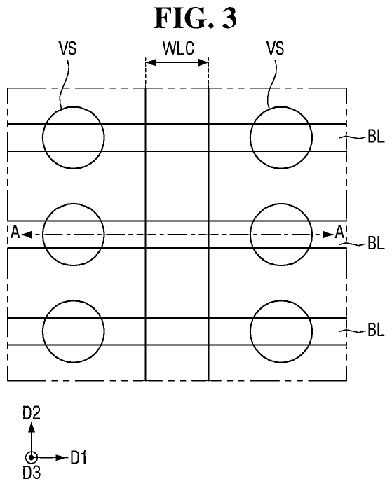

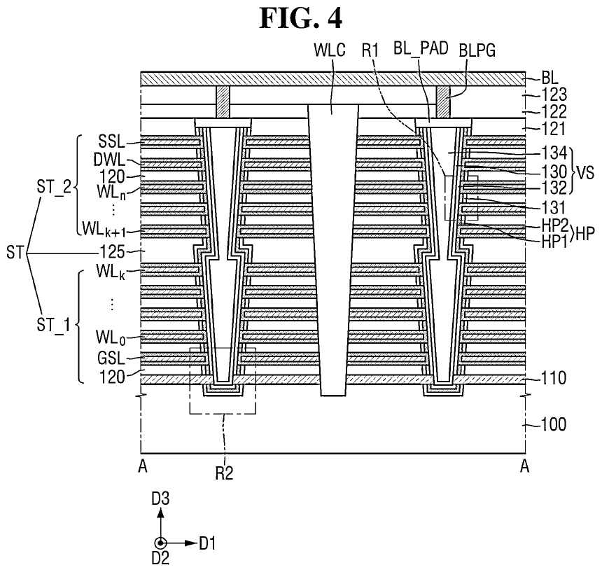

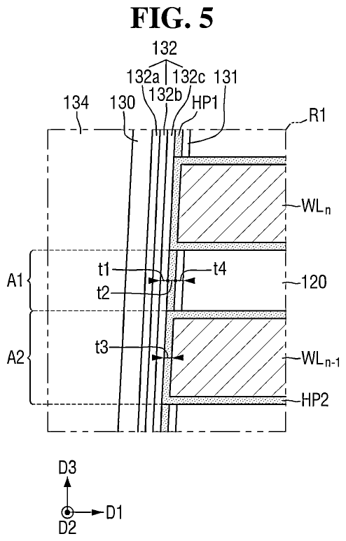

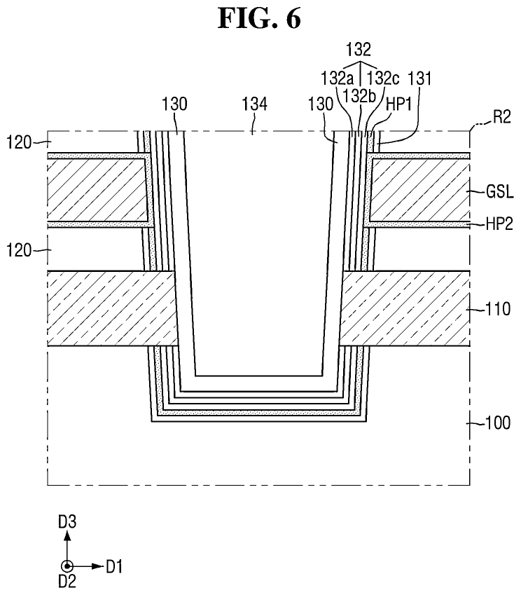

FIG. 3 is a schematic layout diagram for describing the semiconductor memory device according to some example embodiments. FIG. 4 is a cross-sectional view taken along line A-A of FIG. 3. FIG. 5 is an enlarged view of area R1 of FIG. 4. FIG. 6 is an enlarged view of area R2 of FIG. 4.

Referring to FIGS. 3 to 6, the semiconductor memory device according to some example embodiments may include a cell substrate 100, a stack structure ST, vertical structures VS, a high-k film HP, a passivation film 131, and a bit line BL.

The cell substrate 100 may include, for example, a semiconductor substrate such as one or more of a silicon substrate, a germanium substrate, or a silicon-germanium substrate. In some example embodiments, the cell substrate 100 may include one or more of a silicon-on-insulator (SOI) substrate, a germanium-on-insulator (GOI) substrate, or the like. In some example embodiments, the cell substrate 100 may include impurities. For example, the cell substrate 100 may include n-type impurities (e.g., one or more of phosphorus (P), arsenic (As), etc.).

In the following description, a surface of the cell substrate 100 on which the stack structure ST is disposed may be referred to as a front side or an upper surface of the cell substrate 100. On the contrary, a surface of the cell substrate 100 opposite to the front side of the cell substrate 100 may be referred to as a back side or a lower surface of the cell substrate 100. In addition, in the following description, the upper side, the lower side, an upper portion, and a lower portion may be based on a third direction D3.

In some example embodiments, first and second directions D1 and D2 may cross each other, and refer to directions in which the upper side of the cell substrate 100 extends, respectively. The third direction D3 may be a direction crossing each of the first and second directions D1 and D2. For example, the third direction D3 may be a direction perpendicular to the first and second directions D1 and D2.

A source layer 110 may be disposed on the cell substrate 100. The source layer 110 may be interposed between the cell substrate 100 and the stack structure ST. For example, the source layer 110 may extend along the upper surface, that is, the front side, of the cell substrate 100. The source layer 110 may be formed to be connected to a vertical channel film 130 of the vertical structure VS. For example, the source layer 110 may penetrate through the channel insulating film 132 and be in contact with the vertical channel film 130. The source layer 110 may be provided as a common source line (e.g., CSL of FIG. 2) of the semiconductor memory device. The source layer 110 may include, for example, polysilicon doped with impurities or a metal, but is not limited thereto.

In some example embodiments, the vertical structure VS may penetrate through the sources layer 110. For example, a lower portion of the vertical structure VS may penetrate through the sources layer 110 and be disposed in the cell substrate 100.

Although not specifically illustrated, a source support layer may be further included on the source layer 110. Each of the source layer 110 and the source support layer may include polysilicon doped with impurities or polysilicon not doped with impurities, but is not limited thereto. The source support layer may be used as a support layer for preventing or reducing the likelihood of a mold stack from collapsing in a replacement process for forming the source layer 110.

In addition, a base insulating film may be interposed between the cell substrate 100 and the source layer 110. The base insulating film may include, for example, at least one of silicon oxide, silicon nitride, and silicon oxynitride, but is not limited thereto.

The stack structure ST may be disposed on the source layer 110. The stack structure ST may include a plurality of conductive lines GSL, WL₀ to WLₙ, DWL, and SSL and a plurality of inter-electrode insulating layers 120 and 125 stacked in the third direction D3. The inter-electrode insulating layers 120 and 125 are disposed between the conductive lines GSL, WL₀ to WLₙ, DWL, and SSL spaced apart from each other in the third direction D3.

The plurality of conductive lines GSL, WL₀ to WLₙ, DWL, and SSL may include a ground selection line GSL, a plurality of word lines WL₀ to WLₙ, a dummy word line DWL, and a string selection line SSL. The ground selection line GSL, the plurality of word lines WL₀ to WLₙ, the dummy word line DWL, and the string selection line SSL may be sequentially stacked on the cell substrate 100.

In FIG. 4 that seven word lines WL₀ to WL, are disposed on the ground selection line GSL, but this is only for convenience of explanation, and the present disclosure is not limited thereto, and the number of word lines may be greater than or less than seven.

In addition, it has been illustrated in FIG. 4 that that the dummy word line DWL is disposed at an upper portion of the stack structure ST, but the present disclosure is not limited thereto. When the cell string CSTR of FIG. 2 does not include the dummy cell DMCT, a conductive line disposed at the upper portion of the stack structure ST may be a word line WLₙ.

The stack structure ST may include a first sub-stack structure ST_1 and a second sub-stack structure ST_2 disposed on the first sub-stack structure ST_1. The first sub-stack structure ST1 may include the ground selection line GSL and some word lines WL₀ to WLₖ. The second sub-stack structure ST2 may include the other word lines WLₖ₊₁ to WLₙ, the dummy word line DWL, and the string selection line SSL. Here, n is a natural number greater than k. In some example embodiments, n may be 2k+1; however, example embodiments are not limited thereto, and n may be greater than or less than 2k+1.

An inter-electrode insulating layer 125 between the word line WLₖ positioned at the uppermost portion of the first sub-stack structure ST_1 and the word line WLₖ₊₁ positioned at the lowermost portion of the second sub-stack structure ST_2 may have a greater thickness than the inter-electrode insulating layers 120 in the first sub-stack structure ST_1 and the second sub-stack structure ST_2.

When the cell string CSTR of FIG. 2 includes an erase control line between the string selection line SSL and the bit line BL, the stack structure ST may include an additional conductive line disposed on the string selection line SSL.

Although not illustrated, the plurality of conductive lines GSL, WL₀ to WLₙ, DWL, and SSL stacked in the third direction D3 may be stacked in a stair shape.

The conductive lines GSL, WL₀ to WLₙ, DWL, and SSL may include, for example, a conductive material. The conductive lines GSL, WL₀ to WLₙ, DWL, and SSL may include, for example, a metallic material. In the semiconductor memory device according to some example embodiments, the conductive lines GSL, WL₀ to WLₙ, DWL, and SSL may include the same material, may not include any different material, and may have the same conductive film stack structure, respectively. The conductive lines GSL, WL₀ to WLₙ, DWL, and SSL may be formed at the same level. Here, the term “same level” refers to formation by the same fabricating process.

The conductive lines GSL, WL₀ to WLₙ, DWL, and SSL may include, for example, a metal such as tungsten (W), cobalt (Co), or nickel (Ni), but a type of metal is not limited thereto. FIG. 4 illustrates that the conductive lines GSL, WL₀ to WLₙ, DWL, and SSL are formed as a single film, but this is only for convenience of explanation, and the present disclosure is not limited thereto.

The inter-electrode insulating layers 120 and 125 may include, for example, silicon oxide, but are not limited thereto.

A cutting line WLC may be disposed within the stack structure ST. The cutting line WLC may penetrate through the stack structure ST.

The cutting line WLC may extend in the second direction D2 to cut the stack structure ST. The cutting line WLC may cut the conductive lines GSL, WL₀ to WLₙ, DWL, and SSL. Adjacent cut lines WLC may be spaced apart from each other in the first direction D1.

The cutting line WLC may include, for example, at least one of silicon oxide, silicon nitride, silicon oxynitride, and a low-k material. The low-k material may include, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or combinations of two or more thereof, but is not limited thereto.

In the semiconductor memory device according to some example embodiments, the cutting line WLC may not include a conductive material. That is, the cutting line WLC may be made of only an insulating material. Unlike illustrated, the cutting line WLC may include a plurality of films.

The vertical structure VS extends in the third direction D3. The vertical structure VS may penetrate through the stack structure ST. The vertical structure VS may include the conductive lines GSL, WL₀ to WLₙ, DWL, and SSL.

Referring to FIG. 5, the vertical structure VS may include first areas A1 adjacent to the inter-electrode insulating layers 120 and 125 in the first direction D1 and second areas A2 adjacent to the conductive lines GSL, WL₀ to WLₙ, DWL, and SSL in the first direction D1. The first area A1 and the second area A2 may be adjacent to each other in the third direction D3. The first areas A1 may refer to areas in which the vertical structure VS and the inter-electrode insulating layers 120 and 125 overlap each other in the first direction D1, and the second areas A2 may refer to areas in which the vertical structure VS and the conductive lines GSL, WL₀ to WLₙ, DWL, and SSL overlap each other in the first direction D1.

Bit line pads BL_PAD are disposed on the vertical structures VS. The bit line pad BL_PAD may include a conductive material. For example, the bit line pad BL_PAD may include a semiconductor material doped with n-type impurities.

The vertical channel film 130 may extend along sidewalls of the conductive lines GSL, WL₀ to WLₙ, DWL, and SSL. In some example embodiments, the vertical structure VS may have a bent portion between the first sub-stack structure ST_1 and the second sub-stack structure ST_2. For example, a width of the vertical structure VS in the first sub-stack structure ST_1 and the second sub-stack structure ST_2 may increase as a distance from the cell substrate 100 increases, and a maximum width of the vertical structure VS in the first sub-stack structure ST_1 may be greater than a minimum width of the vertical structure VS in the second sub-stack structure ST_2.

The vertical structure VS may include the vertical channel film 130 extending in the third direction D3 and a filling pattern 134. The vertical structure VS may include the channel insulating film 132 disposed between the vertical channel film 130 and the conductive lines GSL, WL₀ to WLₙ, DWL, and SSL. The vertical channel film 130 may be disposed between the channel insulating film 132 and the filling pattern 134.

The vertical channel film 130 may be electrically connected to the source layer 110 serving as the common source line. The vertical channel film 130 may be in contact with the bit line pad BL_PAD. The vertical channel film 130 may include sidewall portions extending in the third direction D3 and a bottom portion connecting the sidewall portions of the vertical channel film 130 to each other.

The vertical channel film 130 may extend in the third direction D3 and penetrate through the stack structure ST. The vertical channel film 130 has been illustrated as having a cup shape, but this is only an example. For example, the vertical channel film 130 may have various shapes such as a cylindrical shape, a square pillar shape, and a filled pillar shape.

The vertical channel film 130 may include, for example, a semiconductor material such as single crystal silicon, polycrystalline silicon, an organic semiconductor material, and a carbon nanostructure, but is not limited thereto.

The filling pattern 134 may fill a space defined by the vertical channel film 130. The vertical channel film 130 may extend along sidewalls of the filling pattern 134. The filling pattern 134 may be in contact with the vertical channel film 130. The vertical channel film 130 may be disposed between a bottom surface of the filling pattern 134 and the channel insulating film 132.

The filling pattern 134 may be formed to fill an inner portion of the vertical channel film 130. The filling pattern 134 may include an insulating material such as silicon oxide, but is not limited thereto.

Referring to FIGS. 5 and 6, the channel insulating film 132 may include, for example, a tunnel insulating film 132a, a charge storing film 132b, and a blocking insulating film 132c sequentially disposed on the vertical channel film 130. The tunnel insulating film 132a, the charge storing film 132b, and the blocking insulating film 132c are only examples, but the present disclosure is not limited thereto.

The tunnel insulating film 132a may include, for example, silicon oxide and/or a high-k material (e.g., aluminum oxide (Al₂O₃) and/or hafnium oxide (HfO₂)) having a higher dielectric constant than the silicon oxide. The charge storing film 132b may include, for example, silicon nitride. The blocking insulating film 132c may include, for example, silicon oxide and/or a high-k material (e.g., aluminum oxide (Al₂O₃) or hafnium oxide (HfO₂)) having a higher dielectric constant than the silicon oxide.

The blocking insulating film 132c may be formed at a first thickness t1 on a first high-k metal oxide film HP1 to be described below. For example, the first thickness t1 may be 5 Å to 70 Å, but is not limited thereto.

The high-k film HP may be in contact with the blocking insulating film 132c, on the blocking insulating film 132c. The high-k film HP may include a first high-k metal oxide film HP1 and a second high-k metal oxide film HP2 including a metal material different from that of the first high-k metal oxide film HP1. In some example embodiments, the second high-k metal oxide film HP2 may not include any metallic element of the metal included in the first high-k metal oxide film HP1. In some example embodiments, the first high-k metal oxide film HP1 may not include any metallic element included in the second high-k metal oxide film HP2.

The first high-k metal oxide film HP1 may be disposed on the first areas A1. For example, the first high-k metal oxide film HP1 may be disposed between the blocking insulating film 132c and the inter-electrode insulating layers 120 and 125. The first high-k metal oxide film HP1 may be in contact with the blocking insulating film 132c.

The first high-k metal oxide film HP1 may have or be formed at a second thickness t2 on a passivation film 131 to be described later. For example, the second thickness t2 may be 5 Å to 20 Å, but is not limited thereto.

The second high-k metal oxide film HP2 may be disposed on the second areas A2. For example, the second high-k metal oxide film HP2 may be disposed between the blocking insulating film 132c and the conductive lines GSL, WL₀ to WLₙ, DWL, and SSL. The second high-k metal oxide film HP2 may be in contact with the blocking insulating film 132c.

The second high-k metal oxide film HP2 may be in contact with at least one of the conductive lines GSL, WL₀ to WLₙ, DWL, and SSL. The second high-k metal oxide film HP2 may be formed along a surface of each of the conductive lines GSL, WL₀ to WLₙ, DWL, and SSL and be in contact with each of the inter-electrode insulating layers 120 and 125, a passivation film 131 to be described later, and the first high-k metal oxide film HP1.

The second high-k metal oxide film HP2 may extend in a direction in which it penetrates through the passivation film 131 and the first high-k metal oxide film HP1, that is, in a direction parallel to the first direction D1.

The second high-k metal oxide film HP2 may be formed at a third thickness t3 on the blocking insulating film 132c. For example, the third thickness t3 may be 5 Å to 30 Å, but is not limited thereto. In some example embodiments, the second high-k metal oxide film HP2 may be formed using an atomic layer deposition process (ALD) and/or plasma-enhanced chemical vapor deposition (PECVD).

The first and second high-k metal oxide films HP1 and HP2 may include different metal atoms, and may not include the same metal atoms. Electronegativity of a metal atom included in the first high-k metal oxide film HP1 may be different from electronegativity of a metal atom included in the second high-k metal oxide film HP2.

For example, each of the first and second high-k metal oxide films HP1 and HP2 may include at least one of aluminum oxide (Al₂O₃), hafnium oxide (HfO), yttrium oxide (Y₂O₃), lanthanum oxide (LaO), and zirconium oxide (ZrO). When the first high-k metal oxide film HP1 includes aluminum oxide, the second high-k metal oxide film HP2 may include metal oxide other than aluminum oxide, such as hafnium oxide, and may not include aluminum oxide.

In some example embodiments, the first and second high-k metal oxide films HP1 and HP2 including different metal materials may be formed in the first areas A1 adjacent to the inter-electrode insulating layers 120 and 125 and the second areas A2 adjacent to the conductive lines GSL, WL₀ to WLₙ, DWL, and SSL, respectively, on the blocking insulating film 132c. For example, a difference between electronegativity of a metal atom and electronegativity of an oxygen atom included in the first high-k metal oxide film HP1 may be smaller than a difference between electronegativity of a metal atom and electronegativity of an oxygen atom included in the second high-k metal oxide film HP2.

In this case, an electron density of the first area A1 bonded to the first and second high-k metal oxide films HP1 and HP2 may be greater than that of the second area A2, such that an energy ban gap of the first area A1 may be greater than an energy band gap of the second area A2. As a result, diffusion of electrons into the first area A1 may be prevented or reduced in likelihood of occurrence, which may be advantageous for electrons trapped by a program to be preserved in the charge storing film 132b.

The passivation film 131 may be disposed between the vertical structure VS and the inter-electrode insulating layers 120 and 125. For example, the passivation film 131 may be disposed between the first high-k metal oxide film HP1 on the blocking insulating film 132c and the inter-electrode insulating layers 120 and 125. The passivation film 131 may be formed at a fourth thickness t4 on the inter-electrode insulating layers 120 and 125. For example, the fourth thickness t4 may be 5 Å to 30 Å, but is not limited thereto.

The passivation film 131 may include silicon oxide, but is not limited thereto. The passivation film 131 may serve to protect the first high-k metal oxide film HP1 so that the first high-k metal oxide film HP1 is not removed in a process of removing a sacrificial layer ILD_SC to be described later.

In FIG. 6, the tunnel insulating film 132a, the charge storing film 132b, and the blocking insulating film 132c may be separated at a lower portion of the vertical channel film 130. The separated tunnel insulating film 132a, charge storing film 132b, and blocking insulating film 132c may expose a portion of the vertical channel film 130. The source layer 110 may be disposed and connected to the vertical channel film 130, between the separated tunnel insulating film 132a, charge storing film 132b, and blocking insulating film 132c.

Although not specifically illustrated, the source layer 110 may be formed on the cell substrate 100. For example, a lower portion of the source layer 110 may be disposed in the cell substrate 100, such that the source layer 110 may be connected to the vertical channel film 130. In this case, the sidewall portions of the vertical channel film 130 may not be exposed, and the bottom portion of the vertical channel film 130 may be exposed. The tunnel insulating film 132a, the charge storing film 132b, and the blocking insulating film 132c between the bottom portion of the vertical channel film 130 and the source layer 110 may be removed. The vertical channel film 130 may be electrically connected to the source layer 110 through the bottom portion of the vertical channel film 130. Although not illustrated, an epitaxial semiconductor pattern may be further disposed between the vertical channel film 130 and the cell substrate 100.

First to third interlayer insulating films 121, 122, and 123 may be sequentially disposed on the stack structure ST. The bit line pad BL_PAD may be disposed in the first interlayer insulating film 121. The cutting line WLC may penetrate through the first interlayer insulating film 121 and the second interlayer insulating film 122. Each of the first to third interlayer insulating films 121, 122, and 123 may include, for example, at least one of silicon oxide, silicon oxynitride, and a low-k material, but is not limited thereto.

The bit line BL may be disposed on the upper stack structure ST. The bit line BL may extend to be elongated in the first direction D1. The bit line BL may be electrically connected to at least one of the vertical channel films 130. The bit line BL may be formed on the third interlayer insulating film 123. The bit line BL may be electrically connected to the bit line pad BL_PAD through a bit line plug BLPG. Each of the bit line BL and the bit line plug BLPG includes a conductive material.

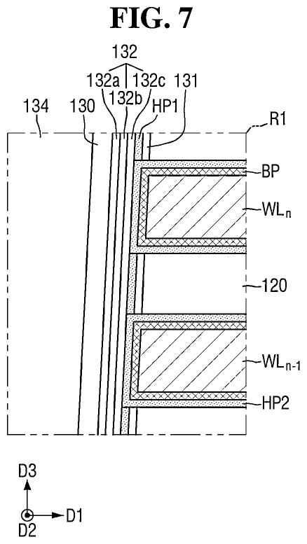

FIG. 7 is a view for describing a semiconductor memory device according to some example embodiments. For reference, FIG. 7 is a view corresponding to FIG. 5.

Referring to FIG. 7, a semiconductor memory device according to some example embodiments may further include a barrier conductive film BP.

The barrier conductive film BP may be disposed between at least one of the conductive lines GSL, WL₀ to WLₙ, DWL, and SSL and the second high-k metal oxide film HP2. The barrier conductive film BP may be disposed between at least one of the plurality of inter-electrode insulating layers 120 and 125 and at least one of the conductive lines GSL, WL₀ to WLₙ, DWL, and SSL, and may be in contact with the second high-k metal oxide film HP2.

The barrier conductive film may include at least one of a metal, metal nitride, metal carbonitride, and a two-dimensional (2D) material. For example, the metal nitride may be or include titanium nitride and/or tantalum nitride. For example, the two-dimensional material may be or include a metallic material and/or a semiconductor material. The two-dimensional material may include a two-dimensional allotrope or a two-dimensional compound.

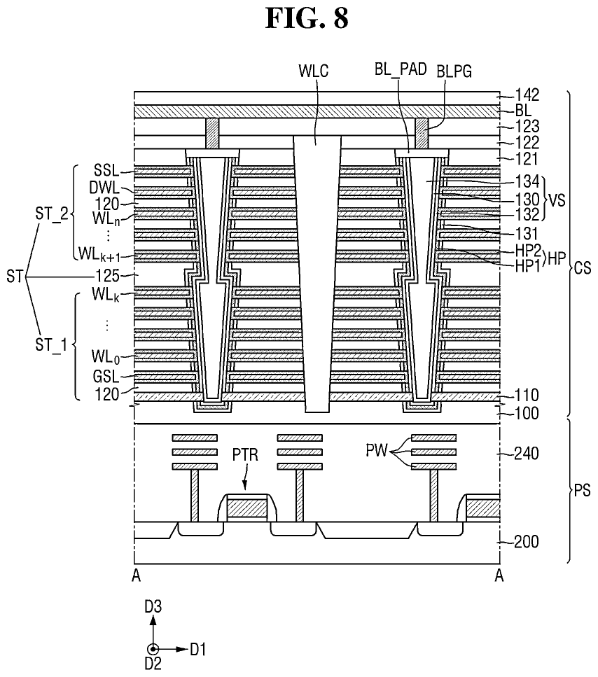

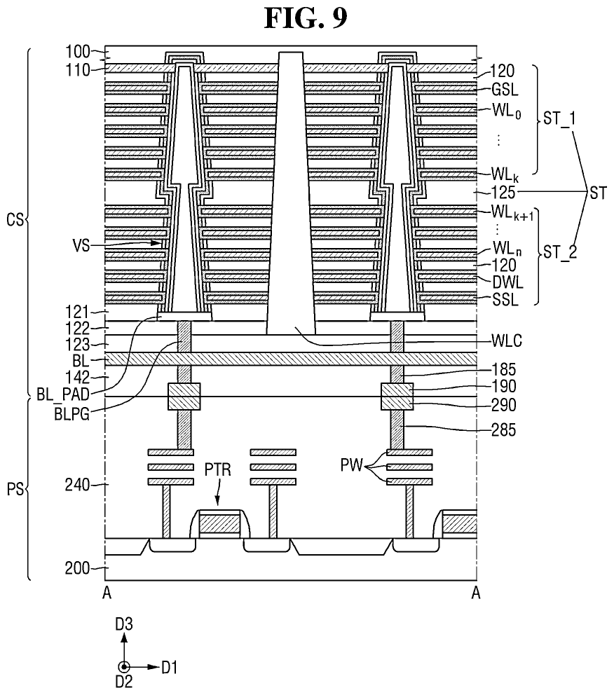

FIGS. 8 and 9 are views for describing semiconductor memory devices according to some example embodiments. For convenience of explanation, contents different from those described with reference to FIGS. 1 to 7 will be mainly described.

Referring to FIGS. 8 and 9, a semiconductor memory device according to some example embodiments may include a memory cell area CS and a peripheral circuit area PS.

The memory cell area CS may include a source layer 110, stack structures ST_1 and ST_2, inter-electrode insulating layers 120 and 125, vertical structures VS, a cutting line WLC, a bit line BL, and a first inter-wiring insulating film 142.

The bit line BL may be formed on the second sub-stack structure ST_2. For example, the first inter-wiring insulating film 142 may be formed on the third interlayer insulating film 123 and the bit line BL may be formed in the first inter-wiring insulating film 142. The bit line BL may extend in the first direction D1 and be connected to the vertical structures VS arranged along the first direction D1. For example, a bit line plug BLPG connected to an upper portion of each vertical structure VS may be formed in the second and third interlayer insulating films 122 and 123. The bit line BL may be electrically connected to the vertical structure VS through the bit line plug BLPG.

The peripheral circuit area PS may include a peripheral circuit cell substrate 100, peripheral circuit elements PTR, and wiring structures PW.

The peripheral circuit cell substrate 100 may include, for example, a semiconductor substrate such as a silicon substrate, a germanium substrate, or a silicon-germanium substrate. Alternatively, the peripheral circuit cell substrate 100 may include one or more of a silicon-on-insulator (SOI) substrate, a germanium-on-insulator (GOI) substrate, or the like.

The peripheral circuit element PTR may be formed on an upper surface of a peripheral circuit substrate 200. The peripheral circuit element PTR may constitute a peripheral circuit (e.g., 30 in FIG. 1) controlling an operation of the semiconductor memory device. For example, the peripheral circuit element PTR may include a control logic (e.g., 37 of FIG. 1), a row decoder (e.g., 33 of FIG. 1), a page buffer (e.g., 35 of FIG. 1), and the like. In the following description, a surface of the peripheral circuit substrate 200 on which the peripheral circuit element PTR is disposed may be referred to as a front side of the peripheral circuit substrate 200. On the contrary, a surface of the peripheral circuit substrate 200 opposite to the front side of the peripheral circuit substrate 200 may be referred to as a back side of the peripheral circuit substrate 200.

The peripheral circuit element PTR may include, for example, a transistor, but is not limited thereto. For example, the peripheral circuit element PTR may include not only various active elements such as transistors, but also various passive elements such as capacitors, resistors, and inductors.

Referring to FIG. 8, in the semiconductor memory device according to some example embodiments, a back side of the source layer 110 may face a front side of the peripheral circuit cell substrate 100. For example, a second inter-wiring insulating film 240 covering the peripheral circuit element PTR may be formed on the upper surface of the peripheral circuit substrate 200. The source layer 110 may be formed on an upper surface of the second inter-wiring insulating film 240.

The wiring structure PW connected to the peripheral circuit element PTR may be formed in the second inter-wiring insulating film 240. The bit line BL, the respective conductive lines GSL, WL₀ to WLₙ, DWL, and SSL, and the source layer 110 may be electrically connected to the peripheral circuit element PTR.

Referring to FIG. 9, in the semiconductor memory device according to some example embodiments, an upper surface of the source layer 110 faces a front side of the peripheral circuit substrate 200.

For example, the semiconductor memory device according to some example embodiments may have a chip to chip (C2C) structure. The C2C structure may refer to a structure in which an upper chip including the memory cell area CS is fabricated on a first wafer (e.g., the first source layer 110), a lower chip including the peripheral circuit area PS is fabricated on a second wafer (e.g., the peripheral circuit substrate 200) different from the first wafer, and the upper chip and the lower chip are then connected to each other by a bonding method.

As an example, the bonding method may refer to a method of electrically connecting first bonding pads 190 formed on the uppermost metal layer of the upper chip and second bonding pads 290 formed on the uppermost metal layer of the lower chip to each other. For example, when the first bonding pad 190 and the second bonding pad 290 are made of copper (Cu), the bonding method may be a Cu—Cu bonding method. However, this is only an example, and the first bonding pad 190 and the second bonding pad 290 may also be made of various other metals such as one or more of aluminum (Al) or tungsten (W). The first bonding pads 190 and the bit line BL may be connected to each other through first vias 185 and the second bonding pads 290 may be connected to the wiring structures PW through second vias 285.

As the first bonding pad 190 and the second bonding pad 290 are bonded to each other, the bit line BL, the respective conductive lines GSL, WL₀ to WLₙ, DWL, and SSL, and the source layer 110 may be electrically connected to the peripheral circuit element PTR.

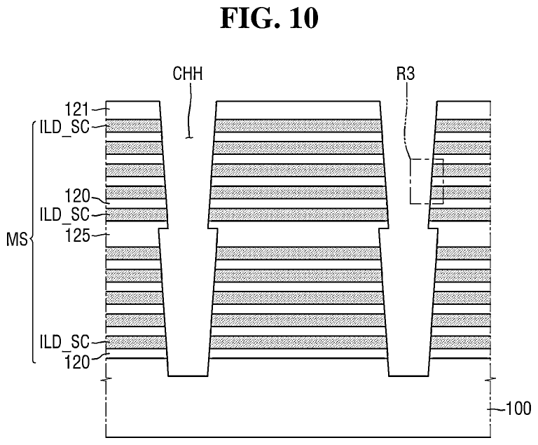

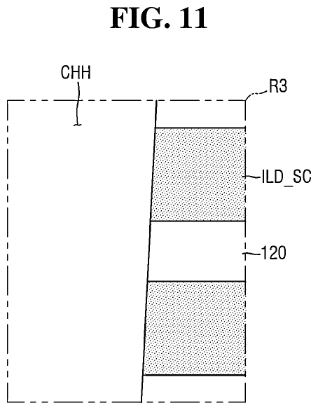

FIGS. 10 to 23 are views for describing intermediate steps of a method of fabricating a semiconductor memory device according to some example embodiments. For reference, FIGS. 10, 12, 14, 16, 18, 20, and 22 are schematic views corresponding to FIG. 4. FIGS. 11, 13, 15, 17, 19, 21, and 23 are enlarged views of areas R3 of FIGS. 10, 12, 14, 16, 18, 20, and 22. For convenience of explanation, contents different from those described with reference to FIGS. 1 to 9 will be mainly described.

Referring to FIGS. 10 and 11, a mold structure MS in which the inter-electrode insulating layers 120 and 125 and mold sacrificial layers ILD_SC are alternately stacked may be formed on the cell substrate 100. The mold structure MS may refer to a pre-stack structure ST. For example, the mold sacrificial layer ILD_SC may include silicon nitride.

Although not specifically illustrated, an alternative insulating layer for forming the source layer 110 may be formed on the cell substrate 100.

Subsequently, channel holes CHH may be formed in the mold structure MS.

More specifically, a portion of the mold structure MS in which the inter-electrode insulating layers 120 and the mold sacrificial layers ILD_SC are alternately stacked may be formed on the cell substrate 100. Subsequently, lower channel holes for forming the vertical structures VS (see FIG. 4) may be formed, and may be then filled with sacrificial patterns.

After the sacrificial patterns are formed, the rest portion of the mold structure MS in which the inter-electrode insulating layers 120 and 125 and the mold sacrificial layers ILD_SC are alternately stacked may be formed. The first interlayer insulating film 121 may be formed on the mold structure MS.

Subsequently, upper channel holes aligned with the lower channel holes and exposing the sacrificial patterns in the lower channel holes may be formed in the rest portion of the mold structure MS and the first interlayer insulating film 121.

The sacrificial patterns in the lower channel hole may be removed, and channel holes CHH in which the lower channel holes and the upper channel holes are connected to each other may be then formed.

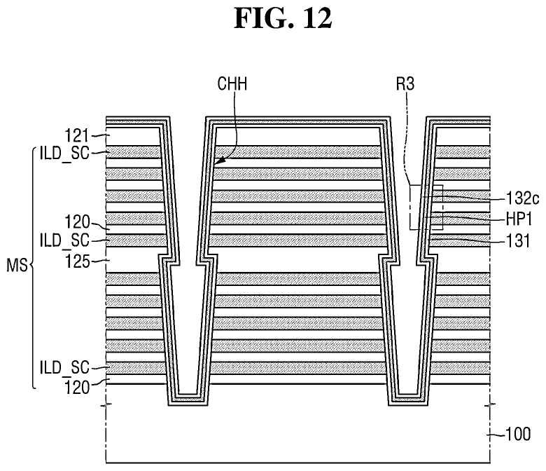

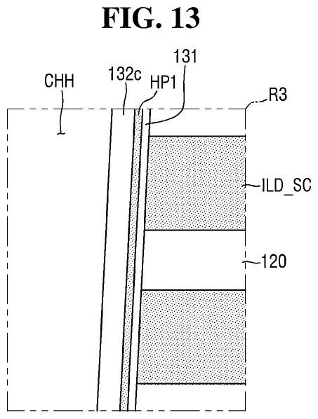

Referring to FIGS. 12 and 13, the passivation film 131 may be formed along profiles of the channel holes CHH in the channel holes CHH. The passivation film 131 may be formed on sidewalls and bottom surfaces of the channel holes CHH and on an upper surface of the first interlayer insulating film 121.

Thereafter, the first high-k metal oxide film HP1 may be formed on the passivation film 131. The first high-k metal oxide film HP1 may be formed along a profile of the passivation film 131.

Thereafter, the blocking insulating film 132c may be formed on the first high-k metal oxide film HP1. The blocking insulating film 132c may be formed along a profile of the first high-k metal oxide film HP1.

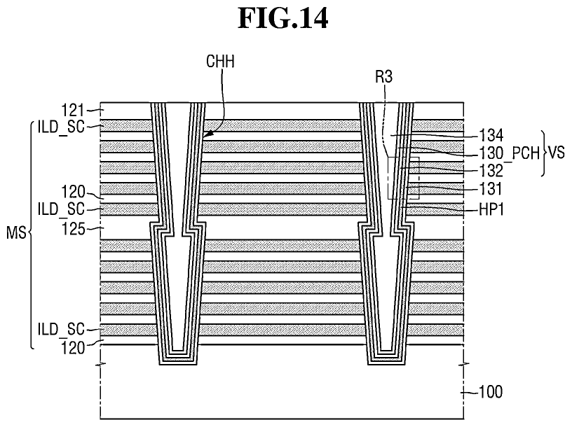

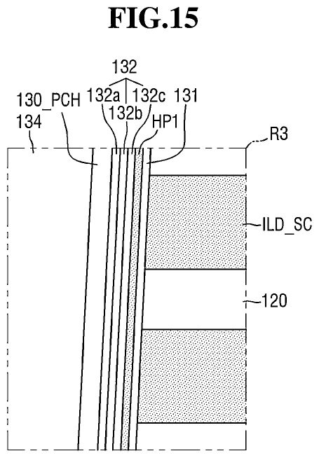

Referring to FIGS. 14 and 15, the charge storing film 132b and the tunnel insulating film 132a may be sequentially formed on the blocking insulating film 132c to form the channel insulating film 132.

A pre-channel film 130_PCH may be formed on the channel insulating film 132. The pre-channel film 130_PCH may be formed along a profile of the channel insulating film 132. The pre-channel film 130_PCH may be formed along the upper surface of the first interlayer insulating film 121 as well as the sidewalls of the channel holes CHH.

The pre-channel film 130_PCH may include a polycrystalline semiconductor material, for example, polysilicon.

The filling pattern 134 may be formed on the pre-channel film 130_PCH.

For example, in the channel holes CHH, the passivation film 131 and the first high-k metal oxide film HP1 are formed, and the vertical structures VS including the vertical channel insulating film 132, the vertical channel film 130, and the filling pattern 134 are formed.

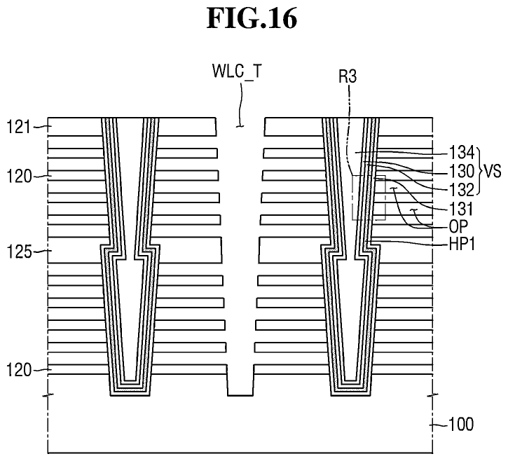

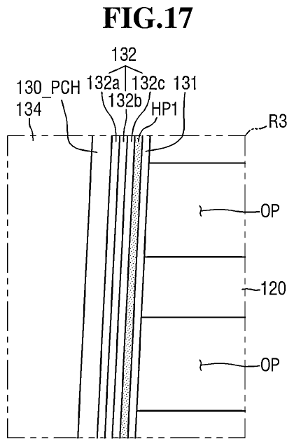

Referring to FIGS. 16 and 17, a cutting line trench WLC_T penetrating through the mold structure MS and the first interlayer insulating film 121 may be formed.

Although not specifically illustrated, the bit line pads BL_PAD may be formed in the channel holes CHH by removing portions of the passivation film 131, the first high-k metal oxide film HP1, and the vertical structures VS. The cutting line trench WLC_T may further penetrate through an interlayer insulating film formed on the bit line pads BL_PAD.

After the cutting line trench WLC_T is formed, the mold sacrificial layers ILD_SC may be removed. In this case, a plurality of mold sacrificial layers ILD_SC are removed, such that openings OP may be formed and portions of the passivation film 131 may be exposed.

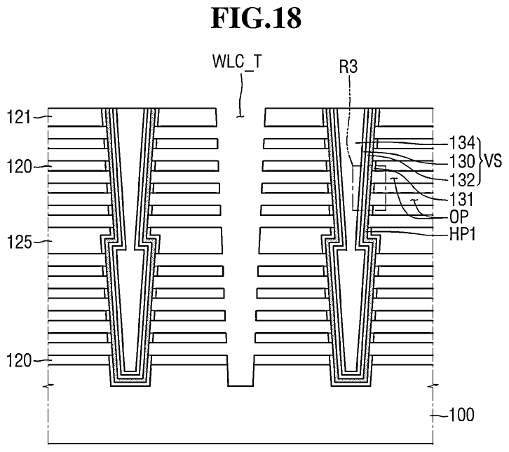

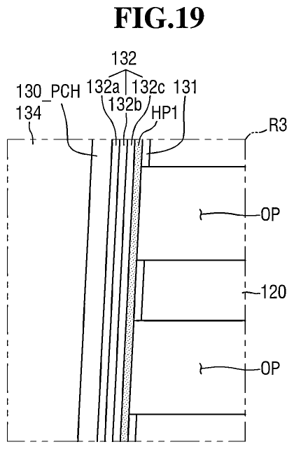

Referring to FIGS. 18 and 19, the exposed portions of the passivation film 131 may be removed to expose portions of the first high-k metal oxide film HP1.

The removing of the exposed portions of the passivation film 131 may be performed by an etching process using a material having etch selectivity with respect to silicon oxide. For example, the passivation film 131 may be removed by SCI cleaning using an ammonia-based material.

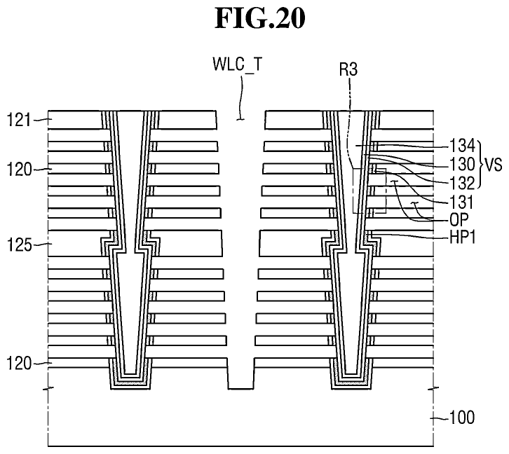

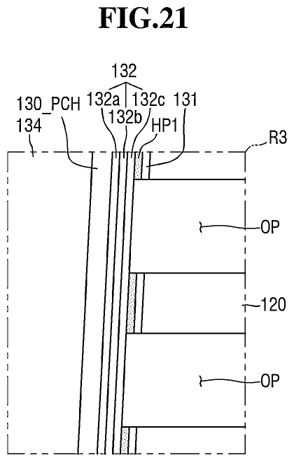

Referring to FIGS. 20 and 21, the exposed portions of the first high-k metal oxide film HP1 may be removed to expose portions of the blocking insulating film 132c.

The removing of the exposed portions of the first high-k metal oxide film HP1 may be performed by a wet etching process using a material having etch selectivity with respect to the first high-k metal oxide film HP1, e.g., with a material that etches different films at different etch rates. For example, an ammonia-based, hydrofluoric acid-based, phosphoric acid-based, sulfuric acid-based, or acetic acid-based material may be used as such a material.

For example, portions of the first high-k metal oxide film HP1 may be removed using high-selectivity nitride (HSN) including a phosphoric acid.

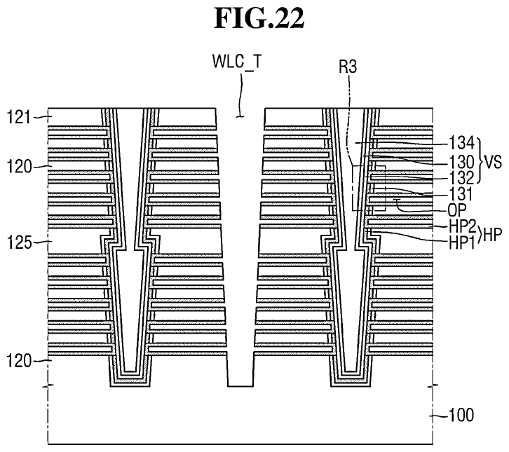

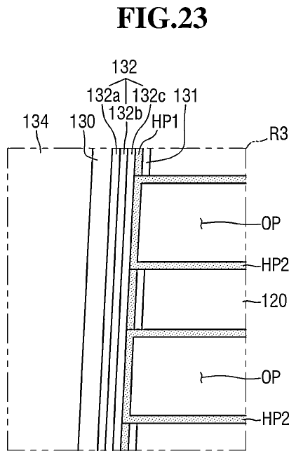

Referring to FIGS. 22 and 23, the second high-k metal oxide film HP2 may be formed on the exposed portions of the blocking insulating film 132c.

The second high-k metal oxide film HP2 may be formed along surfaces of the inter-electrode insulating layers 120 and 125, a surface of the passivation film 131, and a surface of the first high-k metal oxide film HP1.

Although not specifically illustrated, the second high-k metal oxide film HP2 may be further formed along side surfaces of the first interlayer insulating film 121 and side surfaces of the inter-electrode insulating layers 120 and 125 exposed by the cutting line trench WLC_T as well as along the openings OP. The second high-k metal oxide film HP2 formed along the side surfaces of the first interlayer insulating film 121 and the side surfaces of the inter-electrode insulating layers 120 and 125 may be removed thereafter.

Thereafter, the conductive lines GSL, WL₀ to WLₙ, DWL, and SSL may be formed in areas in which the mold sacrificial layers ILD_SC are removed.

For example the mold sacrificial layers ILD_SC may be replaced with the conductive lines GSL, WL₀ to WLₙ, DWL, and SSL through a replacement metal gate process.

In addition, the cutting line WLC filling the cutting line trench WLC_T may be formed.

Accordingly, the semiconductor memory device according to some example embodiments may be formed.

Meanwhile, the semiconductor memory device as illustrated in FIG. 7 may be formed by further forming the barrier conductive film BP between the conductive lines GSL, WL₀ to WLₙ, DWL, and SSL and the inter-electrode insulating layers 120 and 125.

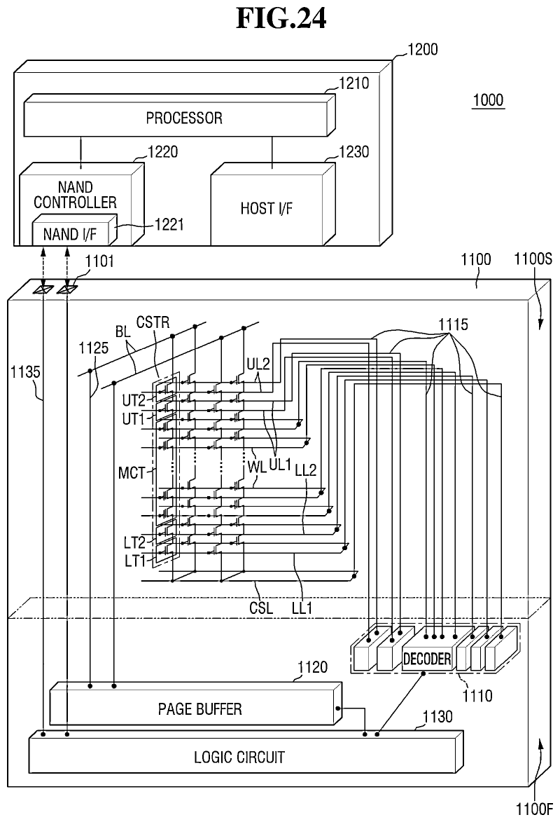

FIG. 24 is an illustrative block diagram for describing an electronic system according to some example embodiments.

Referring to FIG. 24, an electronic system 1000 according to some example embodiments may include a semiconductor memory device 1100 and a controller 1200 electrically connected to the semiconductor memory device 1100. The electronic system 1000 may be a storage device including one semiconductor memory device 1100 or a plurality of semiconductor memory devices 1100 or an electronic device including the storage device. For example, the electronic system 1000 may be a solid state drive (SSD) device, a universal serial bus (USB), a computing system, a medical device, or a communication device including one semiconductor memory device 1100 or a plurality of semiconductor memory devices 1100.

The semiconductor memory device 1100 may be or may include a non-volatile memory device (e.g., a NAND flash memory device), and may be, for example, the semiconductor memory device described above with reference to FIGS. 1 to 23. The semiconductor memory device 1100 may include a first structure 1100F and a second structure 1100S on the first structure 1100F. In some example embodiments, the first structure 1100F may also be disposed next to the second structure 1100S. The first structure 1100F may be a peripheral circuit structure including a decoder circuit 110, a page buffer 1120, and a logic circuit 1130. The second structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to some example embodiments.

In some example embodiments, the upper transistors UT1 and UT2 may include a string selection transistor SST (see FIG. 2), and the lower transistors LT1 and LT2 may include a ground selection transistor GST (see FIG. 2). The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection wirings 1115 extending from the first structure 1100F to the second structure 1100S. The bit lines BL may be electrically connected to the page buffer 1120 through second connection wirings 1125 extending from the first structure 1110F to the second structure 1100S.

In the first structure 1100F, the decoder circuit 1110 and the page buffer 1120 may execute a control operation for at least one of the plurality of memory cell transistors MCT. The decoder circuit 1110 and the page buffer 1120 may be controlled by the logic circuit 1130. The semiconductor memory device 1100 may communicate with the controller 1200 through input/output pads 1101 electrically connected to the logic circuit 1130. The input/output pads 1101 may be electrically connected to the logic circuit 1130 through input/output connection wirings 1135 extending from the first structure 1100F to the second structure 1100S.

The controller 1200 may include a processor 1210, a NAND controller 1220, and a host interface 1230. In some example embodiments, the electronic system 1000 may include a plurality of semiconductor memory devices 1100, and in this case, the controller 1200 may control the plurality of semiconductor memory devices 1100.

The processor 1210 may control an overall operation of the electronic system 1000 including the controller 1200. The processor 1210 may operate according to predetermined firmware, and may access the semiconductor memory device 1100 by controlling the NAND controller 1220. The NAND controller 1220 may include a NAND interface 1221 processing communication with the semiconductor memory device 1100. A control command for controlling the semiconductor memory device 1100, data to be written to the memory cell transistors MCT of the semiconductor memory device 1100, data to be read from the memory cell transistors MCT of the semiconductor memory device 1100, and the like, may be transmitted through the NAND interface 1221. The host interface 1230 may provide a communication function between the electronic system 1000 and an external host. When a control command is received from the external host through the host interface 1230, the processor 1210 may control the semiconductor memory device 1100 in response to the control command.

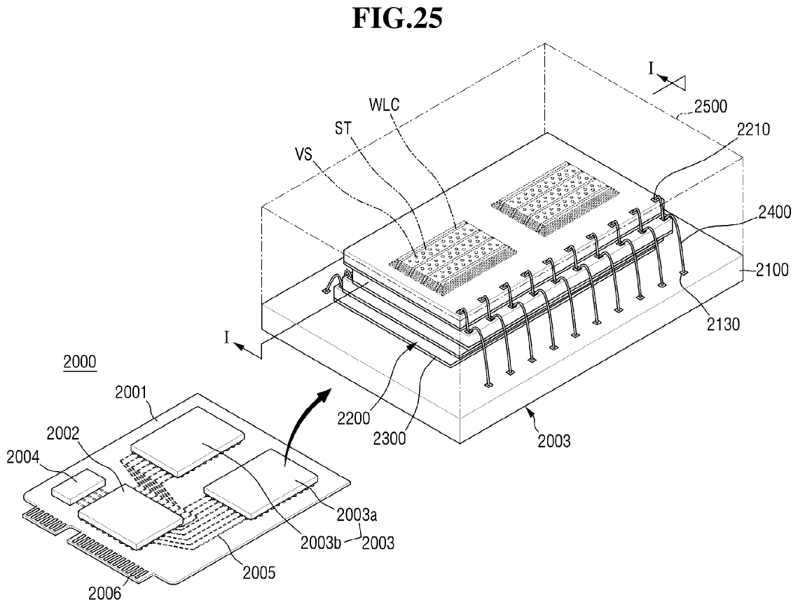

FIG. 25 is an illustrative perspective view for describing an electronic system according to some example embodiments.

Referring to FIG. 25, an electronic system according to some example embodiments may include a main board 2001 and a main controller 2002, one or more semiconductor packages 2003, and a dynamic random access memory (DRAM) 2004 that are mounted on the main board 2001. The semiconductor package 2003 and the DRAM 2004 may be connected to the main controller 2002 by wiring patterns 2005 formed on the main board 2001.

The main board 2001 may include a connector 2006 including a plurality of pins coupled to an external host. The number and an arrangement of pins in the connector 2006 may be changed depending on a communication interface between the electronic system 2000 and the external host. In some example embodiments, the electronic system 2000 may communicate with the external host according to any one of interfaces such as universal serial bus (USB), peripheral component interconnect express (PCI-Express), serial advanced technology attachment (SATA), and M-Phy for universal flash storage (UFS). In some example embodiments, the electronic system 2000 may operate by power received from the external host through the connector 2006. The electronic system 2000 may further include a power management integrated circuit (PMIC) distributing the power received from the external host to the main controller 2002 and the semiconductor package 2003.

The main controller 2002 may write data to or read data from the semiconductor package 2003, and may improve an operation speed of the electronic system 2000.

The DRAM 2004 may be a buffer memory for alleviating a speed difference between the semiconductor package 2003, which is a data storage space, and the external host. The DRAM 2004 included in the electronic system 2000 may operate as a kind of cache memory, and may provide a space for temporarily storing data in a control operation for the semiconductor package 2003. When the electronic system 2000 includes the DRAM 2004, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, the semiconductor chips 2200 disposed on the package substrate 2100, adhesive layers 2300 disposed on lower surfaces of the semiconductor chips 2200, connection structures 2400 electrically connecting the semiconductor chips 2200 to the package substrate 2100, and a molding layer 2500 covering the semiconductor chips 2200 and the connection structures 2400 on the package substrate 2100.

The package substrate 2100 may be a printed circuit board including package upper pads 2130. Each of the semiconductor chips 2200 may include input/output pads 2210. The input/output pads 2210 may correspond to the input/output pads 1101 of FIG. 24. Each of the semiconductor chips 2200 may include a stack structure ST, vertical structures VS, and cutting lines WLC. Each of the semiconductor chips 2200 may include the semiconductor memory device described above with reference to FIGS. 1 to 23.

In some example embodiments, the connection structures 2400 may be bonding wires electrically connecting the input/output pads 2210 to the package upper pads 2130. Accordingly, in each of the first semiconductor package 2003a and the second semiconductor package 2003b, the semiconductor chips 2200 may be electrically connected to each other in a bonding wire manner, and be electrically connected to the package upper pads 2130 of the package substrate 2100. In some example embodiments, in each of the first semiconductor package 2003a and the second semiconductor package 2003b, the semiconductor chips 2200 may be electrically connected to each other by connection structures including through silicon vias (TSVs) instead of bonding wire-type connection structures 2400.

In some example embodiments, the main controller 2002 and the semiconductor chips 2200 may be included in one package. In some example embodiments, the main controller 2002 and the semiconductor chips 2200 may be mounted on a separate interposer substrate different from the main board 2001, and the main controller 2002 and the semiconductor chips 2200 may be connected to each other by wirings formed on the interposer substrate.

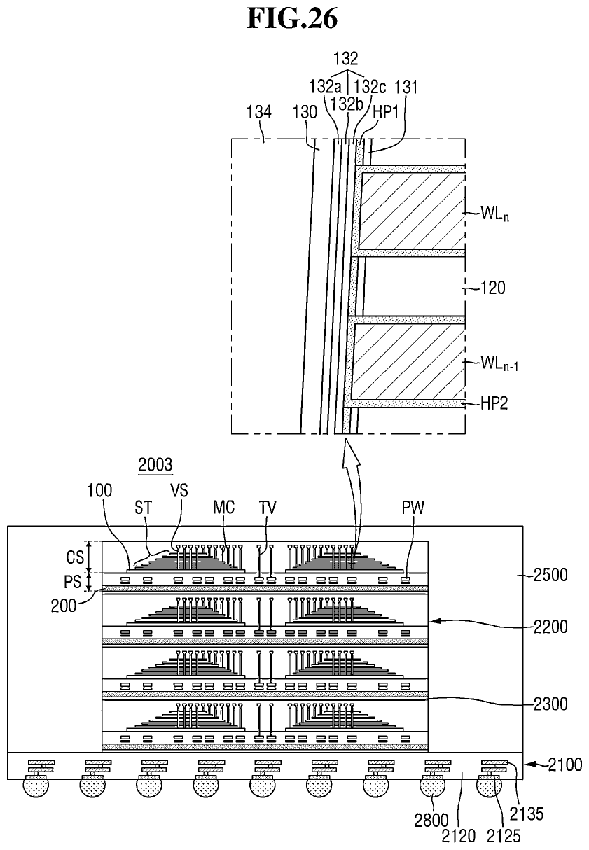

FIG. 26 is a schematic cross-sectional view of a semiconductor package according to some example embodiments. FIG. 26 conceptually illustrates an area taken along line I-I′ of the semiconductor package 2003 of FIG. 25.

Referring to FIG. 26, in some example embodiments, the package substrate 2100 may be a printed circuit board. The package substrate 2100 may include a package substrate body part 2120, upper pads 2135 disposed on an upper surface of the package substrate body part 2120, lower pads 2125 disposed on or exposed through a lower surface of the package substrate body part 2120, and internal wirings electrically connecting the upper pads 2135 and the lower pads 2125 to each other in the package substrate body part 2120. The upper pads 2135 may be electrically connected to the connection structures 2400. The lower pads 2125 may be connected to the wiring patterns 2005 of the main board 2001 of the electronic system 2000 as illustrated in FIG. 25 through conductive connectors 2800.

Each of the semiconductor chips 2200 may include the semiconductor memory device described above with reference to FIGS. 1 to 23. For example, each of the semiconductor chips 2200 may include a peripheral circuit area PS and a memory cell area CS stacked on the peripheral circuit area PS. As an example, the memory cell area CS may include the cell substrate 100, the stack structure ST, the vertical structures VS, the high-k film HP, the passivation film 131, and the bit line BL described above with reference to FIGS. 1 to 23. Meanwhile, when the word lines WL are stacked in a stair shape, the memory cell area CS may further include a cell contact MC electrically connected to one of the word lines WL and a through contact TV electrically connected to the peripheral circuit area PS.

Exemplary embodiments of the present disclosure have been described hereinabove with reference to the accompanying drawings, but the present disclosure is not limited to the above-described exemplary embodiments, and may be implemented in various different forms, and one of ordinary skill in the art to which the present disclosure pertains may understand that the present disclosure may be implemented in other specific forms without changing the technical spirit or essential features of the present disclosure. Therefore, it is to be understood that the example embodiments described above are illustrative rather than being restrictive in all aspects.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Various example embodiments have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the exemplary embodiments described above are illustrative rather than being restrictive in all aspects. Additionally example embodiments are not necessarily mutually exclusive with one another. For example, some example embodiments may include one or more features described with reference to one or more drawings, and may also include one or more other features described with reference to one or more other drawings

What is claimed is:

1. A semiconductor memory device comprising:
a stack structure on a substrate, extending in a first direction, and including gate electrode layers and insulating layers stacked alternately with each other;
a vertical structure including a vertical channel film extending in a second direction crossing the first direction and a channel insulating film on the vertical channel film and having first areas adjacent to the insulating layers and second areas adjacent to the gate electrode layers; and
a high-k film on the channel insulating film,
wherein the high-k film includes a first high-k metal oxide film between the first areas and the insulating layers and in contact with the first areas, and a second high-k metal oxide film between the second areas and the gate electrode layers and in contact with the second areas, and
the first and second high-k metal oxide films include different metal materials.

2. The semiconductor memory device of claim 1, wherein
the channel insulating film includes a tunnel insulating film, a charge storing film, and a blocking insulating film that are sequentially arranged on the vertical channel film, and
each of the first and second high-k metal oxide films is in contact with the blocking insulating film.

3. The semiconductor memory device of claim 2, wherein the blocking insulating film has a first thickness on the first high-k metal oxide film and includes silicon oxide.

4. The semiconductor memory device of claim 1, further comprising:
a passivation film between the first high-k metal oxide film and the insulating layers.

5. The semiconductor memory device of claim 4, wherein the passivation film has a second thickness on the insulating layer and includes silicon oxide.

6. The semiconductor memory device of claim 1, wherein the second high-k metal oxide film is arranged along a surface of the gate electrode layer and is in contact with each of the insulating layer and the first high-k metal oxide film.

7. The semiconductor memory device of claim 2, wherein
the first high-k metal oxide film has a third thickness on the blocking insulating film, and
the second high-k metal oxide film has a fourth thickness on the blocking insulating film.

8. The semiconductor memory device of claim 1, further comprising:
a barrier conductive film between the gate electrode layers and the second high-k metal oxide film.

9. The semiconductor memory device of claim 1, wherein a difference between electronegativity of a metal atom and electronegativity of an oxygen atom of the first high-k metal oxide film is smaller than a difference between electronegativity of a metal atom and electronegativity of an oxygen atom of the second high-k metal oxide film.

10. The semiconductor memory device of claim 1, wherein each of the first and second high-k metal oxide films includes at least one of aluminum oxide, hafnium oxide, yttrium oxide, lanthanum oxide, and zirconium oxide.

11. A semiconductor memory device comprising:
a stack structure on a substrate and including gate electrode layers and insulating layers stacked alternately with each other;
a vertical structure including a vertical channel film and a channel insulating film and extending in a direction in which the vertical structure penetrates through the stack structure, the channel insulating film including a tunnel insulating film, a charge storing film, and a blocking insulating film sequentially disposed on the vertical channel film and having first areas adjacent to the insulating layers and second areas adjacent to the gate electrode layers;
a passivation film between the channel insulating film and the insulating layers;
a first high-k metal oxide film on the first areas and in contact with the blocking insulating film; and
a second high-k metal oxide film on the second areas and in contact with the blocking insulating film,
wherein the first and second high-k metal oxide films include different metal materials.

12. The semiconductor memory device of claim 11, wherein the second high-k metal oxide film extends in a direction in which the second high-k metal oxide film penetrates through the passivation film and the first high-k metal oxide film.

13. The semiconductor memory device of claim 11, further comprising:
a barrier conductive film between the gate electrode layers and the insulating layers and in contact with the second high-k metal oxide film.

14. The semiconductor memory device of claim 11, wherein a difference between electronegativity of a metal atom and electronegativity of an oxygen atom of the first high-k metal oxide film is smaller than a difference between electronegativity of a metal atom and electronegativity of an oxygen atom of the second high-k metal oxide film.

15. The semiconductor memory device of claim 11, wherein each of the first and second high-k metal oxide films includes at least one of aluminum oxide, hafnium oxide, yttrium oxide, lanthanum oxide, and zirconium oxide.

16. A method of fabricating a semiconductor memory device, comprising:
forming a pre-stack structure on a substrate, the pre-stack structure including sacrificial layers and insulating layers that are alternately stacked;
forming channel holes penetrating through the pre-stack structure;
sequentially forming a passivation film and a first high-k metal oxide film in the channel holes;
sequentially forming a blocking insulating film, a charge storing film, a tunnel insulating film, and a pre-channel film on the first high-k metal oxide film;
removing the sacrificial layers to expose portions of the passivation film;
removing the exposed portions of the passivation film to expose portions of the first high-k metal oxide film;
removing the exposed portions of the first high-k metal oxide film to expose portions of the blocking insulating film;
forming a second high-k metal oxide film including a metal material different from that of the first high-k metal oxide film so as to be in contact with the exposed blocking insulating film; and
forming gate electrode layers on the second high-k metal oxide film.

17. The method of fabricating a semiconductor memory device of claim 16, wherein the removing of the exposed portions of the passivation film is performed using a material having etch selectivity with respect to silicon oxide.

18. The method of fabricating a semiconductor memory device of claim 16, wherein the removing of the exposed portions of the first high-k metal oxide film is performed using a material including a phosphoric acid.

19. The method of fabricating a semiconductor memory device of claim 16, wherein
the first high-k metal oxide film is formed between the insulating layers and the blocking insulating film, and
the second high-k metal oxide film is formed between the gate electrode layers and the blocking insulating film.

20. The method of fabricating a semiconductor memory device of claim 16, further comprising:
forming a barrier conductive film between the gate electrode layers and the insulating layers.
